(19) United States
(12) Patent Application Publication
(10) Pub. No.: US 2004/0049592 A1
(43) Pub. Date: Mar. 11, 2004

(54) Method of clock recovery in a TMDS repeater

(76) Inventor: Alexander Yurusov, Taipei (TW)

Correspondence Address: ALEXANDER YURUSOV, 5F, NO. 17, HANG SHENG EAST ROAD, PANCHIAO, TAIPEI, 220, TW

(21) Appl. No.: 10/065,004

(22) Filed: Sep. 9, 2002

(51) Int. Cl. G06F 15/16; H03M 5/00; H04J 3/04

(52) U.S. Cl. 709/231; 341/58; 370/535

(57) ABSTRACT

A method of clock recovery in digital transmission systems based on a transition minimized differential scaling (TMDS) is described. Repeater based on the said method allows a TMDS transmission over long lines to a plurality of TMDS receivers without accumulating of phase distortions.

### BACKGROUND OF INVENTION

1. Technical Field.

The present invention relates to computer systems in general and, more particularly, to a transmission of a TMDS coded serialized video data over long lines to a plurality of TMDS receivers, integrated into video display devices.

2. Related Art.

A prior art high speed serial video signal transmission system, described in the U.S. Pat. No. 5,974,464, comprises a graphic controller, video transmitter, 3 pairs of data wires and 1 pair of clock wires forming a TMDS line, video receiver and LCD panel as a display device. The above structure is shown in FIG. 1.

Nowadays computer systems with a plurality of video displays are widely used. An example of a computer system shows the same content on a plurality of video displays is a public presentation system that can be used during conferences, public events, or in purposes of public information or commercial purposes. Video displays in a such kind of a public broadcasting system usually are located far from a video source computer.

The prior art system described above, however, allows one display device with a TMDS receiver for one computer with a TMDS transmitter with a limited length of a TMDS line comprising 3 pairs for data and 1 pair for clock.

In order to connect several video displays to a computer over a TMDS line it is possible to build a repeater comprising one TMDS receiver and several TMDS transmitters. However, several of the said above repeaters, connected in serial in order to extend TMDS line length or increase amount of connected video displays, cause visible distortion of a displayed video because of accumulation of phase distortions happened in cables, receivers and transmitters.

### SUMMARY OF INVENTION

It is an object of the present invention to provide a method of clock recovery in a transition minimized differential scaling (TMDS) digital transmission systems. This method allows building a TMDS repeater comprising one TMDS receiver, one or more TMDS transmitters and a recovery circuit that reconstructs original video data signal and does not accumulate phase distortions happened in cables, receivers and transmitters.

The recovery method is based on using a quartz clock for TMDS transmitters instead of the clock received over a TMDS line. A dual port first-in-first-out (FIFO) memory is used for buffering data from a TMDS receiver to TMDS transmitters. It is necessary to use the said FIFO memory buffer because the clock obtained from a quartz oscillator onboard a repeater cannot exactly match frequency and phase of a clock received over TMDS line by a TMDS receiver.

Digital video signal over TMDS line has a data disable interval between lines of video data. During this interval no high-speed video data is transmitted, but only low frequency signals of vertical and horizontal synchronization and optional control signals. Time to receive a line of digital video data depends on the received TMDS clock frequency and is different from time to transmit the same line of video data, which depends on a quartz oscillator clock frequency. Time from a data disable interval is used to compensate the said above time difference and FIFO memory is used to buffer a portion of digital video data line. In principle, the said time difference cannot be longer than time of a data disabled interval.

### BRIEF DESCRIPTION OF DRAWINGS

FIG. 1 is a block diagram of a prior art system.

FIG. 2 is a block diagram of a typical public broadcasting system.

FIG. 3 is a block diagram of a repeater based on a prior art system.

FIG. 4 is a block diagram of a repeater with a clock recovery circuit.

FIG. 5 is a flowchart of the operation of a control unit.

### DETAILED DESCRIPTION

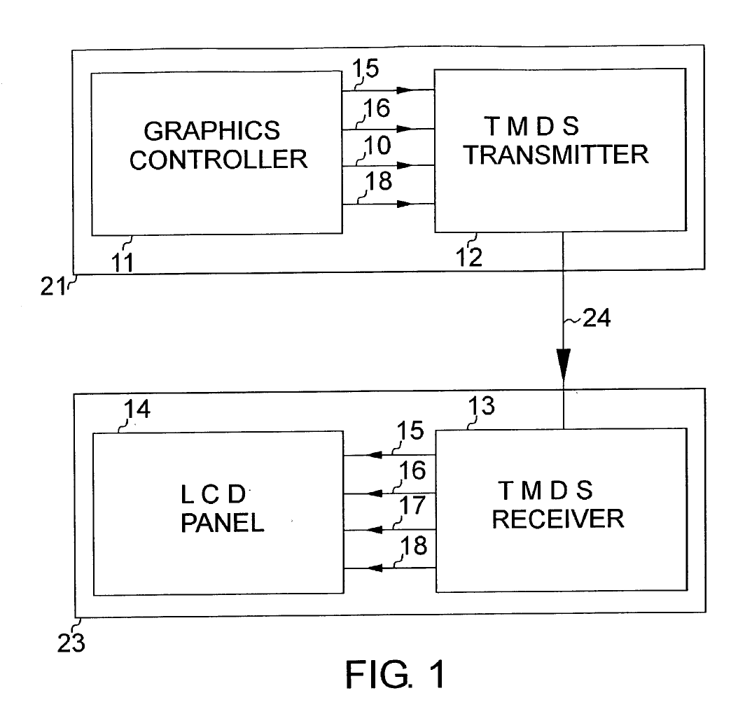

FIG. 1 illustrates a prior art system that comprises a graphic controller 11 and TMDS transmitter 12, both located in a computer 21, as well as TMDS receiver 13 and LCD panel 14, located in a digital display device 23. Digital video data is transmitted from a computer 21 to a digital display device 23 though a TMDS line 24 that usually comprises 3 pairs for data and one pair for clock.

TMDS transmitter 12 during data enable interval, when data enable (DE) signal 16 is high, serializes active video data 15 obtained from a graphic controller 11 though 24 or 32 conductor wires. During data disabled interval, when DE signal 16 is low, TMDS transmitter encodes and serializes control signals 18. All the mentioned signals are sampled according to a pixel clock 10 from a graphic controller 11.

TMDS receiver 13 de-serializes active video data during data enable interval and de-serializes and decodes control signals during data disable interval. Also TMDS receiver 13 reconstructs a pixel clock. However, compare to the original pixel clock 10, received TMDS clock 17 has a jitter and phase distortion, that limits the further use of this clock.

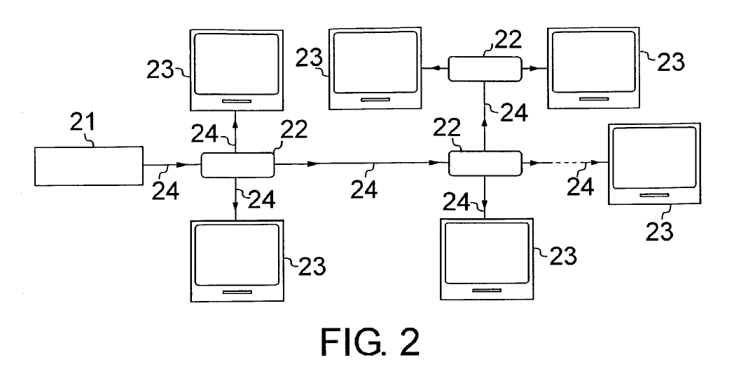

FIG. 2 illustrates an example of the desired public digital video data broadcasting system, where a plurality of digital display devices 23 displays a video content obtained from a computer 21 via a TMDS lines 24. Repeaters 22 are used to receive TMDS data and re-transmit it to a plurality of digital display devices.

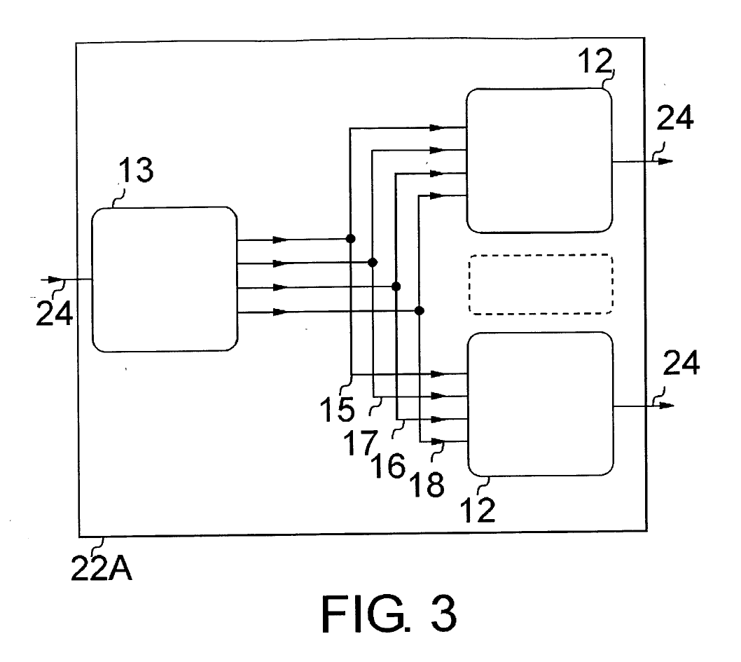

FIG. 3 is a block diagram of a repeater 22A without clock recovery circuit. In this repeater, data de-serialized by a TMDS receiver 13 is shared between several TMDS transmitters 12. All the TMDS transmitters 12 use received TMDS clock 17 with jitter and phase distortion to generate internal serial data clock, which has 10 times higher frequency. Further transmission of a TMDS clock 17 and repeating it by the next repeaters 22A cause a visible distortion of a displayed video due to accumulation of phase distortions happened in cables, receivers and transmitters.

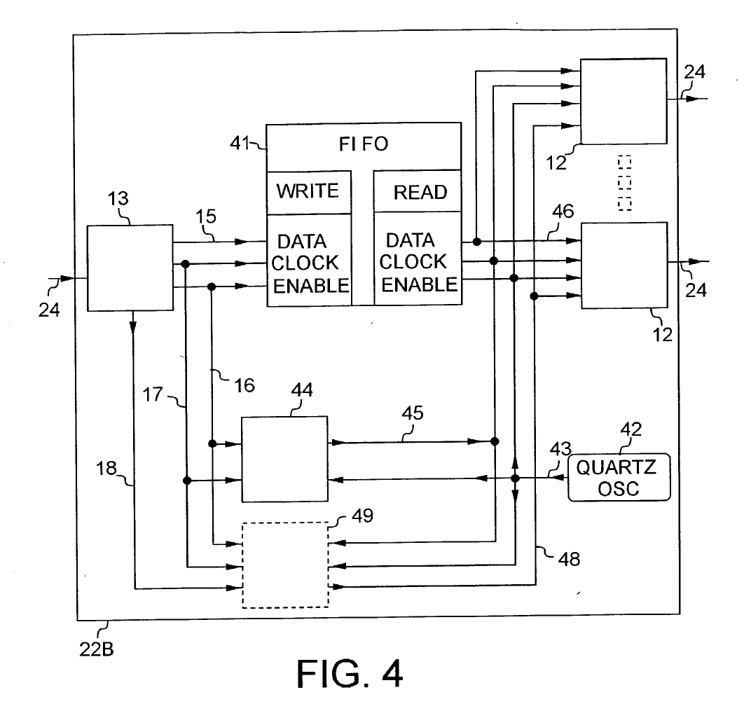

FIG. 4 is a block diagram of a repeater 22B with a clock recovery circuit. TMDS receiver 13 receives a serial digital video data over a TMDS line 24. TMDS receiver 13 outputs parallel video data 15, control signals 18 after de-serializing, as well as TMDS clock 17 and data enable (DE) signal 16. FIFO memory 41 is used to buffer active video data. Control unit 44 generates read enable (RE) signal 45, which is used by a FIFO memory 41 and is used by TMDS transmitters 12 as an outgoing data enable signal. Quartz oscillator 42 provides quartz clock 43 for sampling an outgoing active video data 46, outgoing control signals 48 and RE signal 45. Optional unit 49 is used to reconstruct a signal of a horizontal video synchronization.

As shown in FIG. 4 clock is recovered by a very simple method, just by generating a new clock by a quartz oscillator. However this simple method of clock recovery requires data buffering due to the difference in phase and frequency between incoming TMDS clock and quartz clock. Unit 44 performs control of data buffering.

Control unit 44 has 3 input signals: data enable 16, incoming TMDS clock 17 and quartz clock 43. According to the given signals, control unit 44 generates a read enable (RE) signal 45 that is used as a signal to enable data read from FIFO memory and at the same time it is a data enable signal for TMDS transmitters 12.

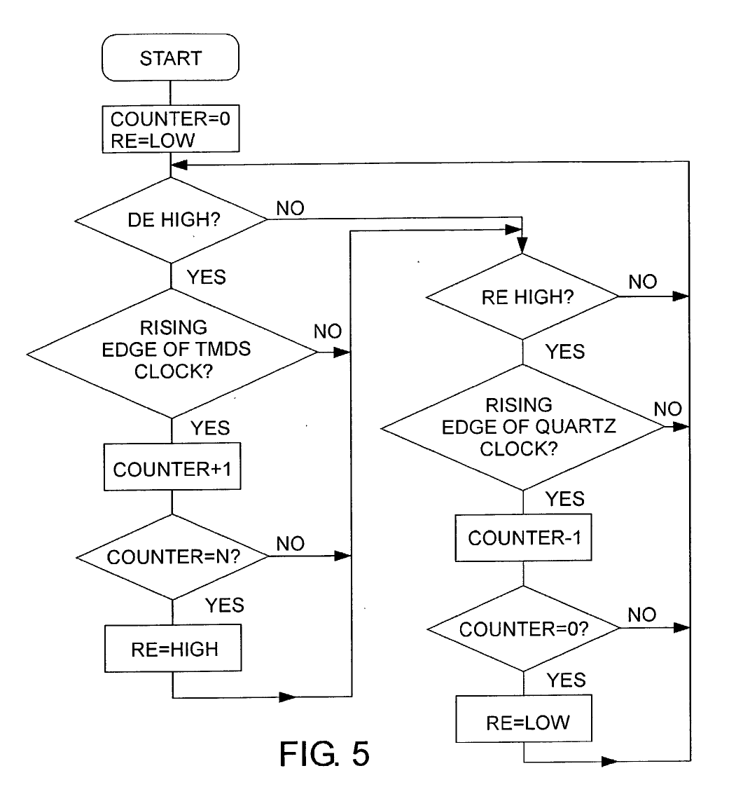

FIG. 5 is a flowchart of the operation of a control unit 44. As shown in a flowchart, unit 44 enables data read (RE) from FIFO memory only after N rising edges of an incoming TMDS clock. At this moment FIFO memory 41 stores N pixels of an active video data. Each rising edge of an incoming TMDS clock 17 stores a pixel data into a FIFO memory 41 and increases a counter in a control unit 44. Each rising edge of a quartz clock 43 reads a pixel from a FIFO memory 41 and decreases a counter in a control unit 44. When a counter reaches zero value, RE signal 45 goes low, disabling data read from a FIFO memory 41 and disabling outgoing TMDS data until the next rising edge of an incoming DE signal 16 and buffering of N pixels of the next video line.

The value N depends on a maximum desired frequency tolerance of a quartz clock 43 from an incoming TMDS clock 17. Also the value N defines the required size of a FIFO memory 41. In order to illustrate the operation principle of a control unit 44 and provide guidance for choosing value N there is an example given below.

For example, for popular computer screen resolution of 768 lines per 1024 horizontal pixels, each line of digital video data consists of an active video data of 1024 pixels and a video blanking period of 320 pixel clocks. Data enable period (DE signal is high) is an active video data period. Data disable period (DE signal is low) is a video blanking period.

Usually clock of 66 MHz is used as a pixel clock for a given above resolution. Assume that the frequency tolerance of the used quartz clock is as big as 100 kHz. That means, that in the worst cases it can as less as 65.9 MHz or as much as 66.1 MHz instead of the desired 66.0 MHz.

Assume that in the first worst case the input TMDS clock 17 frequency is 65.9 MHz and the frequency of the quartz clock 43 is 66.1 MHz. According to the given frequencies the length of data enabled period (DE is high) for incoming video data is equal to 15539 nanoseconds and the length of Data Enable period for outgoing video data is equal to 15492 nanoseconds. Based on the above calculations, transmission time of the outgoing active video line data is 47 nanoseconds less than receiving time of the incoming active video line data. For the given clocks frequencies, 47 nanoseconds is time for the transmission of less than 4 pixels. Thus the value of N can be chosen equal to 4. That means that 4 pixels of an active video data will be buffered in a FIFO memory before TMDS transmitters 12 will begin to transmit the outgoing active video data. As a quartz clock in given case is faster than incoming TMDS clock, at the falling edge of an incoming DE signal a FIFO memory will buffer only one the last pixel data, which will be transmitted out during the next period of a quartz clock.

In the second worst case the input TMDS clock 17 frequency is 66.1 MHz and the frequency of the quartz clock 43 is 65.9 MHz. Transmission time of the outgoing active video line data is 47 nanoseconds longer than receiving time of the incoming active video line data. Thus at the falling edge of an incoming DE signal a FIFO memory will buffer data of the last 8 or 9 pixels. Transmission of an active video line data will be complete during the next 8-9 periods a quartz clock.

Optional unit 49 can be used for the recovery of control signals. Control signals usually include a horizontal synchronization signal, a vertical synchronization signal and several signals for a general purpose control. Control signals are valid only during data disabled interval. Because of a clock recovery described above, the outgoing data disabled interval can have a period different from a period of the incoming data disabled interval and outgoing control signals 48 should be sampled according to the recovered quartz clock.

Usually general-purpose control signals are specified not to have any signal transitions during data disabled interval. This allows direct bypass of all incoming general-purpose control signals to TMDS transmitters 12.

One-pixel jitter of a vertical synchronization signal usually does not cause a video picture distortion on screen of a target display device. This allows direct bypass of a vertical synchronization signal to TMDS transmitters 12.

A jitter of a horizontal synchronization signal can cause a video picture distortion on screen of a target display device when the said display device requires a horizontal synchronization signal. Nowadays a plurality of digital display devices use only data enable signal for synchronization purposes and make no use of horizontal or vertical synchronization signals. However, when a stable horizontal synchronization signal is required, an optional unit 49 can reproduce it.

Use of the described above TMDS repeater with a clock recovery circuit allows building a public digital video data broadcasting system, where is no principle limitations for the quantity of display devices and the length of TMDS data line.

1. A method of clock recovery in a transition minimized differential scaling (TMDS) digital transmission system, where a TMDS receiver receives digital video data according to the received TMDS clock and a TMDS transmitter transmits digital video data according to a quartz clock and a dual port first-in-first-out (FIFO) memory is used to buffer digital video data during an active video period of a video line:

2. A TMDS digital video data repeater, comprising:
a dual port first-in-first-out FIFO memory buffer;
a TMDS receiver writing received data into a dual port FIFO memory buffer according to received TMDS clock;
a quartz oscillator;
one or several TMDS transmitters reading data from a dual port FIFO memory buffer according to the quartz clock;
a circuit to control an outgoing TMDS stream according to an incoming TMDS stream by counting the amount of received and transmitted data and using time of a data disable interval to compensate the speed difference of incoming and outgoing streams caused by a frequency difference between a quartz clock and received TMDS clock.

3. A digital video data display system, comprising:
a computer as a source of a digital video data;
a plurality of TMDS repeaters of claim 2 used to repeat and distribute a digital video data;
a plurality of digital display devices connected to TMDS repeaters of claim 2 and used to display a digital video data.
